(19) United States
(12) Patent Application Publication
(10) Pub. No.: US 2025/0304428 A1
(43) Pub. Date: Oct. 2, 2025

(54) MULTI-SENSOR MEMS OR NEMS MEASURING SYSTEM

(71) Applicant: COMMISSARIAT À L'ENERGIE ATOMIQUE ET AUX ENERGIES ALTERNATIVES, PARIS (FR)

(72) Inventor: Wioletta TRZPIL, GRENOBLE (FR)

(21) Appl. No.: 19/241,261

(22) Filed: Jun. 17, 2025

(30) Foreign Application Priority Data
Jun. 28, 2024 (FR) 2407058

(51) Int. Cl. B81B 3/00; G01D 5/30; G01D 5/353

(52) U.S. Cl. CPC B81B 3/0021; G01D 5/30; G01D 5/353; B81B 2201/0271; B81B 2203/0118

(57) ABSTRACT

A MEMS and/or NEMS measuring system includes: a resonant assembly including a plurality of N resonators indexed i, at least one resonant mechanical element coupled to each resonator, and at least one waveguide to which the optical resonators are coupled, an emission device, an injection device, each resonator of the resonant assembly further being configured to be excited at a mechanical excitation frequency and to modulate the light beam associated with the first excitation frequency, a resonant mechanical element being configured to be excited at a mechanical excitation frequency and to modify an optical transmission or reflection in the vicinity of the optical resonance of the associated resonator, the modification being dependent on a physical quantity to be measured, at least one detector, a demodulation device including a plurality of so-called LIA demodulation modules employing synchronous detection.

### CROSS-REFERENCE TO RELATED APPLICATION

This application claims priority to foreign French patent application No. FR 2407058, filed on Jun. 28, 2024, the disclosure of which is incorporated by reference in its entirety.

### FIELD OF THE INVENTION

The present invention relates to the field of MEMS- or NEMS-based sensors, and more particularly to sensors using an optical resonator coupled to at least one mechanical element, and to networking of these sensors.

### BACKGROUND

MEMS- or NEMS-based sensors based on the interaction of a quantity to be measured with an optical resonator have recently seen increased use and are of very varied nature. By MEMS- or NEMS-based sensor what is meant is any sensor benefiting from the microfabrication techniques of microelectronics.

A sensor of this type comprises an optical resonator RO, also called a photonic cavity, and one or more waveguides GO that are coupled to the optical resonator, as illustrated in FIG. 1. The optical resonator is characterized by at least one resonant wavelength λr associated with a bandwidth of resonance of width λr/Qopt (Qopt being the quality factor of the optical cavity) as illustrated in FIG. 2 which shows the energy E stored in the resonator as a function of wavelength.

The propagation properties of EM waves in the optical resonator are affected by a measurand u (physical quantity to be measured) or a parameter u the response of which depends on a measurand of interest z. A read light beam Fin is injected into the input of the sensor, and the amplitude and/or phase of the light beam propagating through the one or more waveguides coupled to the optical resonator RO is perturbed by the magnitude u. The optical transmission or reflection function of the sensor is thus modified, directly or indirectly, by the physical quantity to be measured. The beam Fout emerges from the output of the sensor and is detected by a photodetector, and a measurement of the magnitude u is deduced from the detected beam.

In the example of FIG. 1, the optical resonator RO is a ring the real and/or imaginary part of the effective propagation index n_{eff}(u) of which depends on u. The propagation speed and/or dissipation rate of the light wave in the optical resonator thus depends on u.

For example, for a sensor intended to identify biological objects, absorption of a given biological body on the surface of the resonator modifies its effective propagation index and changes the position of the resonant wavelength λr(u), u being the amount absorbed. The nature of the body (measurand z) is determined from the amount absorbed.

Thus, the absorbed body is identified via the functionalization layer, which selects the particles to be detected. To give one example of a measurand z in the case of this type of sensor, it is possible to establish a relationship between the parameter u (which corresponds to an amount of substance to be detected) and the measurand z (which may be the concentration of this substance). The two are related by an absorption-desorption process and may be described by a biochemical equilibrium equation.

According to another example, the sensor comprises an optical resonator RO coupled to a mechanical element the movement of which is measured. This type of sensor is called an optomechanical sensor.

FIG. 3 illustrates such a sensor in which the mechanical element is a cantilever P fastened at one end to a stud CP. The read beam is injected into the guide GO and collected on exiting the guide by a grating coupler GC. The movement x of the cantilever (parameter u) in the evanescent field of the optical resonator perturbs the effective index (variation of the gap between the cantilever and the ring). Based on the movement x, the acceleration of a body is for example measured (measurand z).

According to yet another example, the resonant mechanical element is merged with the optical resonator, which then has an optical resonance and a mechanical resonance.

Certain sensors are said to be active, because these sensors use the energy provided by the measurand to carry out the transduction, no external excitation being applied to the sensor: the force of an ultrasonic wave activates the membrane, inertial force sets a moving mass in motion, etc.

The sensors of another class of sensors, called passive sensors, undergo a modification of one of their physical parameters. For example, the resonant frequency of the mechanical system or its quality factor, the electrical resistance of a strain gauge, etc. In this case, it is necessary to provide an external excitation (a bias) to read the parameter. This means of excitation is necessary for certain categories of sensor.

For example, the resonant mechanical element is excited at an external excitation frequency fex lying in the band of mechanical resonance BPm about a mechanical resonant frequency frm.

In another example of a passive sensor, the optical resonator and the mechanical resonator are merged. It is for example a question of a vibrating disc exhibiting both an optical and mechanical resonance: for example a sensor operating in a liquid medium with a view to detecting biological objects (viruses, proteins, etc.) that are deposited on the disc. The additional mass absorbed on the discs is measured (a functionalization layer may or may not be used), allowing the concentration of the biological species to be determined. The mass weighs down the disc, modifying its mechanical resonant frequency. It is a question, according to another example, of an atomic force sensor taking the form of a ring equipped with a resonating tip, such as described in the publication by Allain et al “Optomechanical resonating probe for very high frequency sensing of atomic forces” Nanoscale, 2020, 12, 2939.

In order to multiply the measurements and/or increase the accuracy or functionality of the sensor, it is advantageous to network these active or passive sensors. This then raises the problem of how to read the information associated with each sensor.

Document EP4109049 describes a measuring system SM0 as illustrated in FIG. 4 comprising a plurality of optical resonators coupled to a waveguide and elements associated with the optical resonators. This measuring system allows all the individual information generated by each elementary sensor, consisting of one optical resonator/element, to be collected simultaneously, and therefore all the values measured by all the sensors to be accessed.

The system SM0 comprises a resonant assembly ER comprising one input E and one output S, a plurality of N optical resonators Ri indexed i each exhibiting a resonant wavelength λr,i, and at least one waveguide GO to which the optical resonators are coupled.

The system SM0 also comprises at least one element Eij coupled to each resonator Ri and configured to modify an optical transmission or reflection in the vicinity of the resonance of the associated optical resonator Ri, the modification being dependent on a physical quantity to be measured. The optical resonators are indexed i, i varying from 1 to N, and the elements associated with a resonator i are indexed j: Eij. An assembly Eij/Ri forms one elementary sensor Cij and the assembly ER forms a network of sensors. Within an assembly ER a plurality of types of sensors may be mixed. Examples of resonators Ri are: a guide looped back on itself (such as a ring), a disk, and a photonic crystal.

As explained above, the optical transmission/reflection of a resonator Ri is modified by a physical quantity u, which may either directly be the final physical quantity that it is desired to measure, or a parameter on which the final quantity to be measured z depends. The objective of the measuring system SM0 is to measure the physical quantity u. The value of this parameter u measured by the element Eij associated with the resonator Ri (sensor Cij) is denoted uij, and it will be understood that when u is an intermediate parameter, the measurement zij is then determined from uij.

The measuring system SM0 also comprises an emission device DE configured to emit a plurality of N light beams each having an emission wavelength λi lying in the band of resonance of the associated optical resonator Ri. The spectral band BPopt around the resonant frequency is called the spectral band of resonance of the resonator Ri, and it is characterized by the parameter Qopt as shown in FIG. 2: BPopt=λr/Qopt. The various wavelengths ki must be chosen so as to have separate spectral bands of resonance, to avoid a wavelength emitted by one laser from being able to address two different optical resonators RO.

The system also comprises a modulation device DM configured to modulate each of the light beams at a modulation frequency fmod(i) and an injection device DI configured to superpose the N light beams to form an input beam Bin and to inject the beam into the input of the resonant assembly ER. The input beam Bin is the probe beam, or read beam, that will read the measurements made by the sensors Cij, via the modification of the optical response of the resonators Ri. The output beam of the assembly ER is denoted Bout.

The beams are for example superposed using cube or plate beam splitters, or with an arrayed waveguide grating (AWG). The injection into the waveguide is for example achieved with an optical fibre coupled to a grating coupler, or via edge coupling to an optical fibre positioned in the same plane as the substrate.

The system also comprises at least one detector Det, for example a photodiode, configured to detect a light beam obtained from the output beam Bout, and to generate an electrical output signal Sout.

In FIG. 4 et seq., optical beams have been represented by solid lines and electrical signals by dashed lines, in order to make the diagrams more legible.

According to one example, the emission device DE comprises, for example, N lasers Li emitting beams Bini(i) and the modulation device DM comprises N modulators respectively arranged on the optical paths of the N light beams emitted by the N lasers, and configured to modulate each light beam at the frequency fmod(i). The modulators are for example electro-optical modulators EOM(i) (see FIG. 5).

The modulation device DM performs intensity modulation. This intensity modulation is for example performed directly (modulated lasers), via absorption (electro-optical modulators), or via Mach-Zehnder (MZ) interference or resonator interference.

Lastly, the system SM0 comprises a demodulation device DDM comprising a plurality of demodulation modules 11 employing synchronous detection, for demodulating the output signal, so as to extract characteristic signals Sdemod(i,j) associated with each element Eij, the measured values uij of the physical quantity u being determined from the characteristic signals.

The principle of the system SM0 is that information relating to a wavelength λi is coded with a frequency modulation at fmod(i), allowing this information to be collected not through wavelength demultiplexing but through electronic demodulation processing of synchronous-detection type. The signals at the frequencies of interest are extracted electronically with a very good signal-to-noise ratio. The extraction is achieved via analogue or digital blocks.

In this document it is demonstrated that the information of interest uij is coded on components of the output optical intensity Iₒᵤₜ of angular frequency Δi+/−Ωij, with:
Δi=2·π·fmod(i); Ωᵢⱼ=2·π·fc(i,j); and fc(i,j) the excitation frequency applied to the resonant element Eij.

By virtue of linearization of the transmission functions, the signals of interest are accessible through modulation/demodulation coding/decoding. The use of synchronous detection makes it possible to extract the phase signal directly with a very good SNR. The demodulated signals Sdemod(i,j) make it possible to isolate the measurands associated with each individual photonic sensor Cij because the signals are positioned in different spectral bands.

The synchronous detection is typically implemented using a lock-in amplifier (LIA). The signal is amplified and multiplied by a reference signal (generated by an internal or external oscillator). A low-pass filter with a suitable cut-off frequency performs the integration. The synchronous detection may be performed in analogue or digital. It may be improved by integrating two quadrature channels.

The number of LIA demodulation modules 11 and the choice of the various modulation and demodulation frequencies depend on the type of sensors of the assembly ER and on the selected demodulation architecture.

According to a first option illustrated in FIG. 5, the demodulation takes place in a single stage. The resonant assembly SM0 comprises M resonant elements Eij (Mi per resonator Ri). In the example illustrated in FIG. 5, the demodulation device DDM comprises M LIA demodulation modules configured to perform M demodulations at frequencies fmod(i)+/−fc(i,j), respectively. The advantage is that this architecture comprises only one stage, the information being obtained in a single processing operation. The constraint on the choice of the modulation frequencies is that they must preferably be higher than 10 times the passband of the sensor. In the example of FIG. 5, N=3 and Mi=3 for all the resonators Ri, i.e. M=9. In this case, the demodulation device comprises 9 LIA demodulators 11(i,j).

According to a second option illustrated in FIG. 6, the demodulation takes place in two stages. According to one example, the demodulation device DDM comprises a first stage comprising N LIA demodulation modules 11(i) configured to perform N demodulations at the frequencies fmod(i), respectively, and comprises, for each channel i, one second stage. The second stage comprises either LIA demodulation modules 12(i,j) for performing demodulation at the characteristic frequencies fc(i,j) or spectral filters BPF(i,j) configured to perform spectral filtering around the characteristic frequency fc(i,j).

Which of the two options is chosen depends on the signal to be extracted.

The document EP4109049 also describes a measuring system SM0 (illustrated in FIG. 7) in which the resonant assembly ER comprises 3 disks forming both the optical resonator and the mechanical resonator. The three disks are excited at frequencies fex(1), fex(2) and fex(3) that are generated by 3 oscillators Oscex1, Oscex2, Oscex3, respectively. The three excitation frequencies lie in mechanical spectral bands BPm1, BPm2, BPm3 around the mechanical resonant frequencies frm1, frm2, frm3 of the disks, respectively. The signals V1 (t), V2(t) and V3(t) delivered by the oscillators are transported on the same bus and injected to the three disks, each disk acting as a filter and reacting only to its own resonance. Here there are no elements Eij associated with each resonator, and it is the resonators Ri themselves that act as resonant mechanical element, the disk in this case being referred to as Ri/Ei (dual function).

The modulation frequencies fmod(1), fmod(2) and fmod(3) are generated by three source oscillators Oscs1, Oscs2, Oscs3, respectively. The demodulation frequency fdemod(i)=fmod(i)+/−fex(i) is synthesized from the two signals delivered by the two oscillators Oscsi and Oscexi. The modulation frequencies are typically selected to be between a few kHz and a few GHz.

One drawback of the measuring system SM0 is the use of external modulators for the modulation of the light beams injected into the resonant assembly, this making fabrication complex and preventing a system that is entirely integrated into one chip from being produced. In addition, the modulators are often sensitive to the polarization of the light, and they therefore require additional elements to be used (polarization controllers), this increasing the complexity of the system. Furthermore, the modulators may exhibit significant insertion losses, which must be compensated for by the laser, this leading to additional power consumption.

### SUMMARY OF THE INVENTION

One aim of the present invention is to remedy the aforementioned drawbacks by providing an improved measuring system that does not comprise external modulators, and that has an original resonant assembly.

The first subject of the present invention is a MEMS and/or NEMS measuring system comprising:
a resonant assembly comprising:
   one input and one output,
   a plurality of N resonators OMRi indexed i, each resonator being configured to exhibit both an optical resonance at an optical resonant wavelength and a mechanical resonance at an associated mechanical resonant frequency frm/o(i), said optical resonant wavelengths and said mechanical resonant frequencies all being different,
   at least one resonant mechanical element MEij coupled to each resonator OMRi, j being the index of the resonant mechanical element associated with the resonator OMRi, said resonant mechanical element having a mechanical resonant frequency, said mechanical resonant frequency being, where appropriate, different from the mechanical resonant frequencies of the other resonant mechanical elements coupled to a given resonator,
   at least one waveguide to which the optical resonators are coupled,
an emission device configured to emit a plurality of N light beams each having an emission wavelength λi lying in an optical band of resonance of the associated optical resonator,
an injection device configured to superpose the N light beams to form an input beam and to inject the input beam into the input of the resonant assembly,
   each resonator OMRi of the resonant assembly further being configured to be excited at a mechanical excitation frequency called the first excitation frequency, lying in a first band of mechanical resonance of said resonator, and to modulate the light beam associated with said first excitation frequency,
   a resonant mechanical element being configured to be excited at a mechanical excitation frequency called the second excitation frequency, and to modify an optical transmission or reflection in the vicinity of the optical resonance of said associated resonator, said modification being dependent on a physical quantity to be measured,
at least one detector configured to detect a light beam obtained from the beam output from the resonant assembly and to generate an output signal,
a so-called LIA demodulation device comprising a plurality of demodulation modules employing synchronous detection, for demodulating the output signal,
so as to extract characteristic signals associated with each resonant mechanical element, measured values of said physical quantity being determined from said characteristic signals.

In one embodiment, the resonators are configured so that path lengths of the light in said resonators are different from one resonator to another, a path length being related to the associated optical resonant wavelength by the following formula:

$${λ}_{ri} = \frac{PLi \cdot {n}_{effi}}{m ( i )}$$

with PLi the optical path length of the light in the resonator OMRi,
n_{effi} the effective refractive index of the material of the resonator OMRi,
m(i) an integer greater than or equal to 1 selected for each i.

According to one embodiment, the resonators are discs of radii Ri made of the same material, and that respect the relationship:

$${λ}_{ri} = \frac{2 π Ri \cdot {n}_{eff}}{m ( i )}$$

with n_{eff} the effective refractive index of the material of the discs.

The second subject of the present invention is a MEMS and/or NEMS measuring system comprising:
a resonant assembly comprising:
   one input and one output,
   a plurality of N resonators OMRi indexed i, each resonator being configured to exhibit both an optical resonance at an optical resonant wavelength common to all the resonators and a mechanical resonance at a mechanical resonant frequency specific to each resonator, said mechanical resonant frequencies all being different,
   at least one resonant mechanical element MEij coupled to each resonator OMRi, j being the index of the resonant mechanical element associated with the resonator OMRi, said resonant mechanical element having a mechanical resonant frequency, said mechanical resonant frequency being, where appropriate, different from the mechanical resonant frequencies of the other resonant mechanical elements coupled to a given resonator,
   at least one waveguide to which the optical resonators are coupled, an emission device configured to emit a light beam called the input beam having an optical wavelength λini lying in an optical band of resonance that is identical for all the optical resonators,
an injection device configured to inject said input beam into the input of the resonant assembly,
   each resonator OMRi of the resonant assembly further being configured to be excited at a mechanical excitation frequency, called the first excitation frequency, lying in a first band of mechanical resonance of said resonator, and to modulate the light beam associated with said first excitation frequency,
   a resonant mechanical element being configured to be excited at a mechanical excitation frequency called the second excitation frequency, and to modify an optical transmission or reflection in the vicinity of the optical resonance of said resonator, said modification being dependent on a physical quantity to be measured,
at least one detector configured to detect a light beam obtained from the beam output from the resonant assembly and to generate an output signal,
a so-called LIA demodulation device comprising a plurality of demodulation modules employing synchronous detection, for demodulating the output signal, so as to extract characteristic signals associated with each resonant mechanical element, measured values of said physical quantity being determined from said characteristic signals.

According to one embodiment, the resonators are made of the same material and configured so that the path lengths of the light in said resonators are different from one resonator to another, a path length being related to the optical resonant wavelength by the following formula:

$${λ}_{r} = \frac{PLi \cdot {n}_{eff}}{m ( i )}$$

with PLi the optical path length of the light in each of the resonators OMRi,
n_{eff} the effective refractive index of the material of said resonators OMRi,
m(i) an integer greater than or equal to 1 selected for each i.

According to one embodiment, the resonators are discs of radii Ri made of the same material, and that respect the relationship:

$${λ}_{r} = \frac{2 π Ri \cdot {n}_{eff}}{m ( i )}$$

According to another embodiment, the resonators are made of the same material and have identical dimensions, the various mechanical resonant frequencies being obtained by modification, from one resonator to another, of the positions of elements anchoring said disks.

According to one embodiment (common to both subjects), a resonator is selected from: a disc, a ring, and a racetrack.

According to one embodiment (common to both subjects), a resonator is excited via actuation selected from electrostatic actuation, piezoelectric actuation, and optical actuation.

According to one embodiment (common to both subjects), a resonant mechanical element is selected from a beam, a disc, and a suspended platform.

According to one embodiment (common to both subjects), a resonant mechanical element is excited via actuation selected from electrostatic actuation, piezoelectric actuation, and thermal actuation.

According to one embodiment (common to both subjects), a second excitation frequency of a resonant mechanical element coupled to one resonator is identical to a second excitation frequency of a resonant mechanical element coupled to another resonator.

According to one embodiment (common to both subjects), the resonators are excited at said associated first excitation frequencies via dedicated oscillators, said oscillators forming a first set of oscillators, and said resonant mechanical elements are excited at said second excitation frequencies via dedicated oscillators, said oscillators forming a second set of oscillators.

According to one embodiment (common to both subjects), signals generated by the oscillators of the first set transit over a first common bus for exciting the resonators and/or signals generated by the oscillators of the second set transit over a second common bus for exciting the resonant mechanical elements.

According to one embodiment (common to both subjects), the resonators are actuated via first electrodes that are connected to one other and that are connected to the first bus.

According to one embodiment (common to both subjects), the resonant mechanical elements are actuated via second electrodes that are connected to one another and that are connected to the second bus.

According to one embodiment (common to both subjects), said oscillators of the first and second sets are used to generate demodulation frequencies.

The present invention also relates to a measuring sensor comprising a plurality of M measuring systems according to the second subject of the invention, a measuring system being indexed k and forming a channel k, each channel having an associated resonant wavelength,
said inputs and said outputs merging so that the various channels operate in parallel,
the injection device, the detector and the demodulation device being common to all the channels,
each emission device being configured to emit a light beam having an emission wavelength λk lying in a band of resonance of the associated channel and the injection device being configured to superpose the M light beams to form said input beam.

The following description provides a plurality of examples of embodiment of the device of the invention: these examples do not limit the scope of the invention. These examples of embodiment not only contain the features essential to the invention but also additional features associated with the embodiments in question.

### BRIEF DESCRIPTION OF THE DRAWINGS

The invention will be better understood and other features, aims and advantages thereof will become apparent from the following detailed description, which is provided with reference to the appended drawings, which are given by way of non-limiting example and in which:

FIG. 1, which has already been cited, shows an optical ring resonator according to the prior art.

FIG. 2, which has already been cited, shows the energy E stored in the resonator as a function of wavelength.

FIG. 3, which has already been cited, shows an optomechanical sensor according to the prior art comprising an optical resonator coupled to a mechanical element the movement of which is measured, wherein the mechanical element is a cantilever P fastened at one end to a stud.

FIG. 4, which has already been cited, shows a measuring system according to the prior art comprising a plurality of optical resonators coupled to a waveguide and elements associated with the optical resonators.

FIG. 5, which has already been cited, illustrates a first variant of the measuring system of FIG. 4 in which the demodulation takes place in a single stage.

FIG. 6, which has already been cited, illustrates a second variant of the measuring system of FIG. 4 in which the demodulation takes place in two stages.

FIG. 7, which has already been cited, shows a variant of the measuring system of FIG. 4 in which the resonant assembly comprises disks forming both the optical resonator and the mechanical resonator.

FIG. 8 illustrates a resonator coupled to a waveguide and comprising an associated mechanical element according to the invention.

FIG. 9 illustrates, for a resonator vibrating at the mechanical resonant frequency, the luminous power detected at the output of the waveguide as a function of wavelength.

FIG. 10 illustrates three examples of optomechanical resonators according to the invention.

FIG. 11 illustrates a first variant of the measuring system according to the invention, in which the optomechanical resonators are configured to have optical resonant wavelengths that are all different.

FIG. 12 illustrates a second variant of the measuring system according to the invention, in which the optomechanical resonators are configured to have a common optical resonant wavelength.

FIG. 13 illustrates one embodiment compatible with the two variants in which the demodulation mode is said to be “one-stage”.

FIG. 14 illustrates another embodiment compatible with the two variants in which the demodulation mode is said to be “two-stage”.

FIG. 15 illustrates one embodiment of the system according to the invention in which the first excitation frequencies of the resonators and the second excitation frequencies of the resonant mechanical elements are generated via dedicated oscillators.

FIG. 16 illustrates one embodiment of the system according to the invention in which signals delivered by the oscillators of the first set transit over a first common bus and/or the signals delivered by the oscillators of the second set transit over a second common bus.

FIG. 17 illustrates one embodiment of the system according to the invention in which the resonators are actuated via first electrodes that are connected to one another and that are connected to the first bus, and the resonant mechanical elements are actuated via second electrodes that are connected to one another and that are connected to the second bus.

FIG. 18 illustrates one example of a system according to the first variant of the invention in which the resonant assembly is integrated into a chip.

FIG. 19 illustrates a measuring sensor according to another aspect of the invention, comprising a plurality of systems according to the second variant of the system according to the invention.

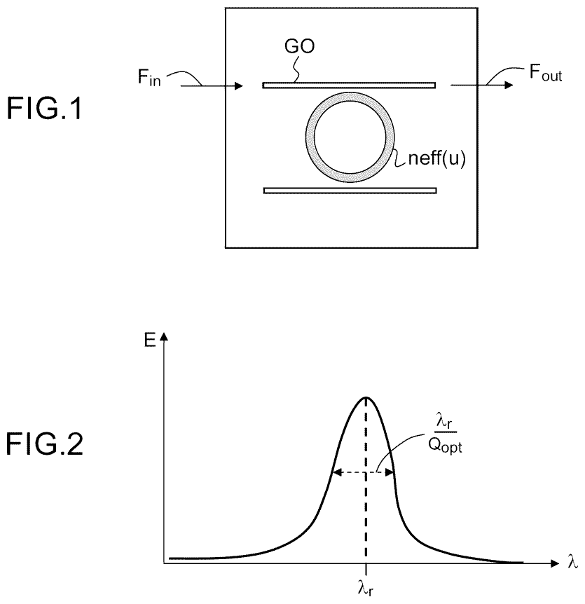

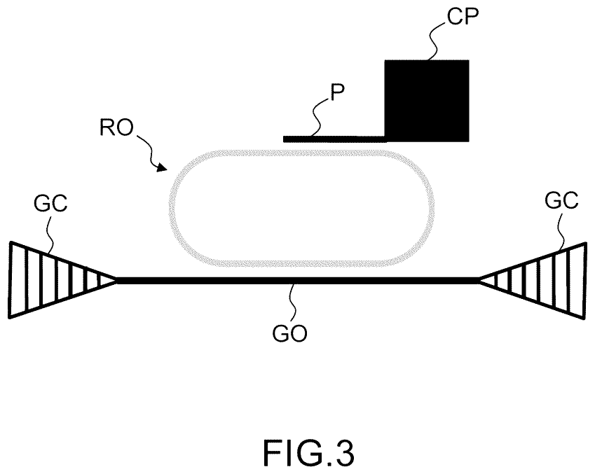

### DETAILED DESCRIPTION

The invention relates to a MEMS and/or NEMS measuring system comprising a resonant assembly, the system according to the invention is identical in certain aspects to the system described in document EP4109049 but has certain differences and is improved in certain ways.

The resonant assembly ENR according to the invention comprises one input E, one output S, and a plurality of N resonators OMRi indexed i, each resonator being configured to exhibit an optical resonance at an optical resonant wavelength (kr or kri see below) and a mechanical resonance at an associated mechanical resonant frequency frm/o(i). The mechanical resonant frequencies frm/o(i) are all different from one another. The resonator OMR is an optomechanical resonator (existence of both optical and mechanical resonance).

Each resonator OMRi is coupled to at least one resonant mechanical element MEij, j being the index of the resonant mechanical element associated with the resonator OMRi. The resonant mechanical element MEij has a mechanical resonant frequency frm/e(i,j). In the case where a resonator is coupled to a plurality of resonant mechanical elements, the mechanical resonant frequencies of the resonant mechanical elements coupled to a given resonator are all different from one another.

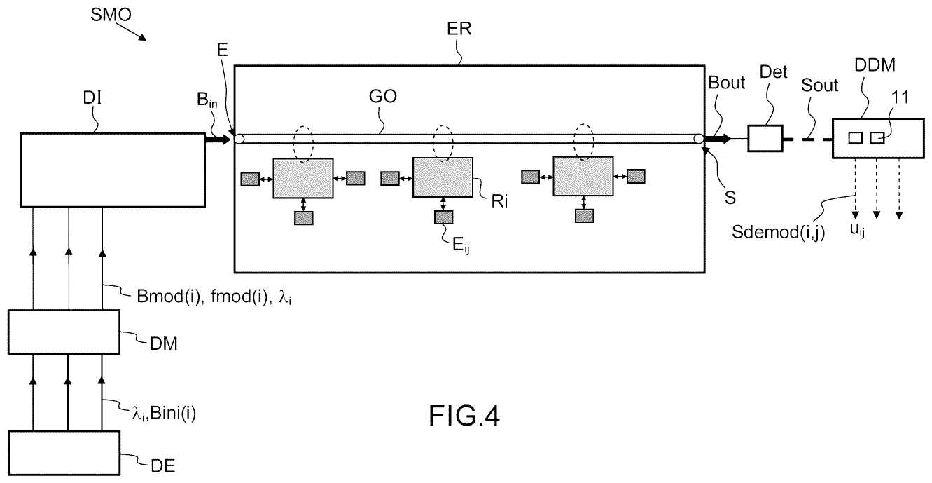

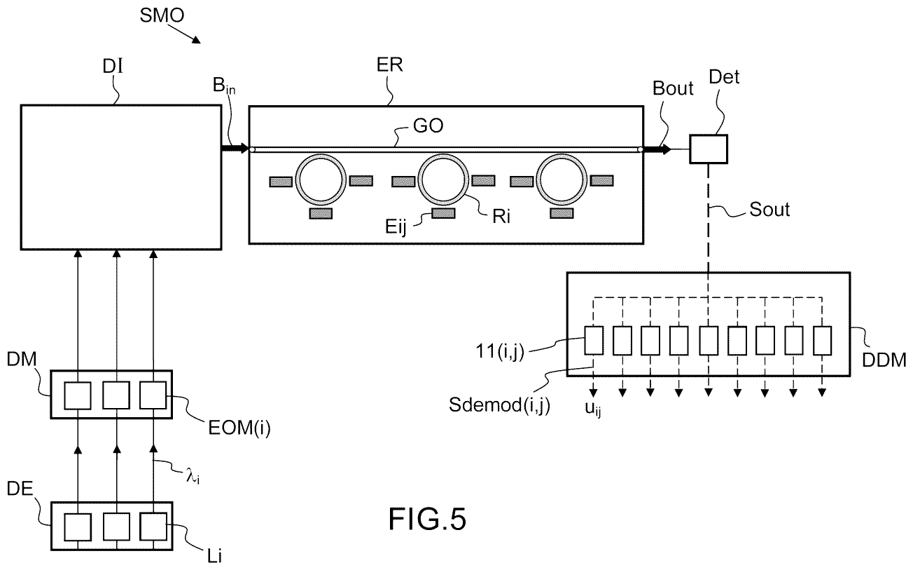

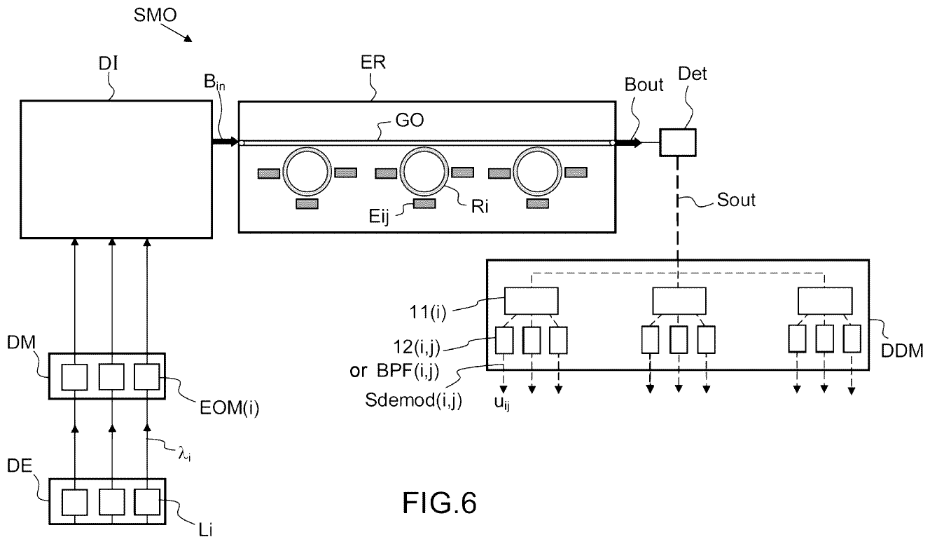

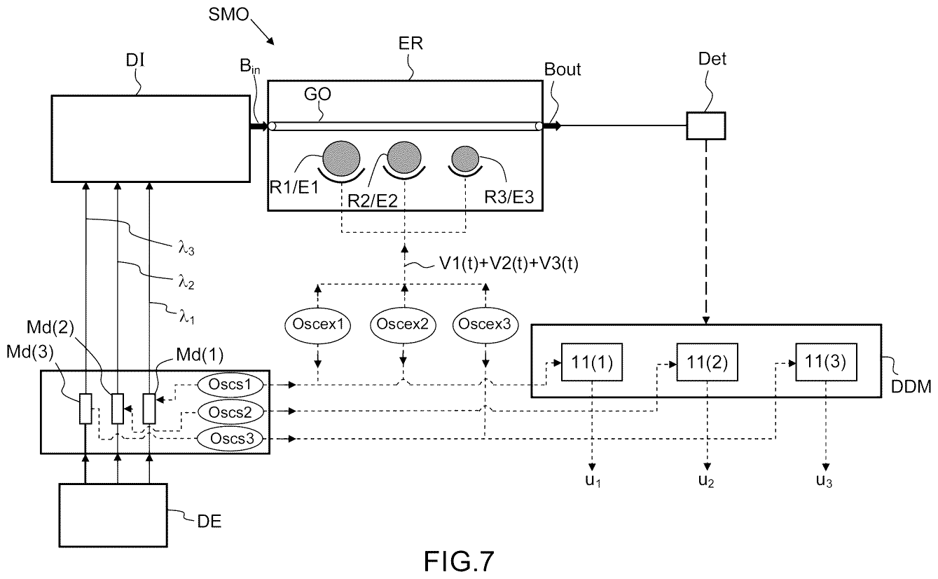

This is a difference with respect to the structure of the resonant assembly of document EP4109049, in which the optical resonators were:
either coupled to resonant mechanical elements and then did not exhibit mechanical resonance (FIG. 4 cited above in the present patent application),
or configured to also exhibit a mechanical resonance, and then were not coupled to any resonant mechanical elements (FIG. 7 cited above in the present patent application).

The optical resonators OMRi are coupled to at least one waveguide GO. It is the association (OMRi, MEij) that forms an elementary sensor Cij.

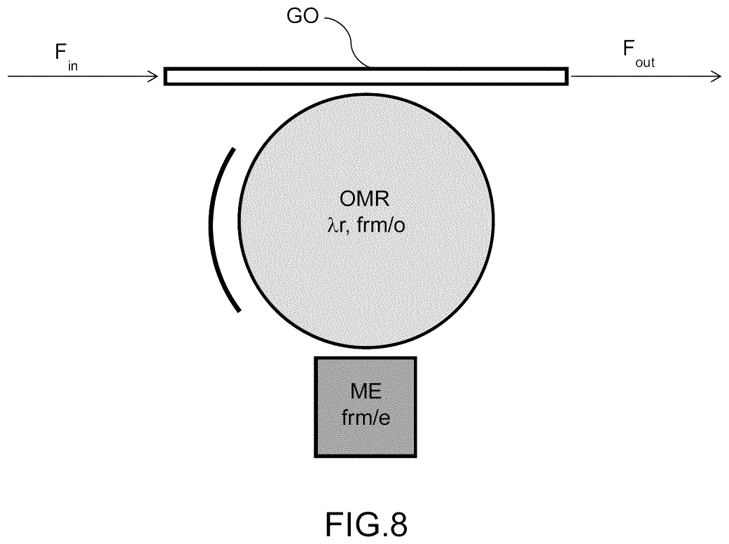

A resonator OMR coupled to a waveguide GO and comprising an associated mechanical element ME is illustrated in FIG. 8. The incoming laser beam, of wavelength λₗₐₛₑᵣ, is denoted Fin and the outgoing laser beam is denoted Fout. The resonator OMR has a resonant wavelength λr and a resonant frequency frm/o.

The resonant wavelength λr is expressed by the equation:

$${λ}_{r} = \frac{PL \cdot {n}_{eff}}{m} , m = 1 , 2 , 3 … \qquad ( 1 )$$

with PL the length of the optical path traced by the light on the perimeter of the resonator, neff the effective index of the material of the resonator, and m a selected integer greater than or equal to 1. Thus, a plurality of optical resonant wavelengths are accessible.

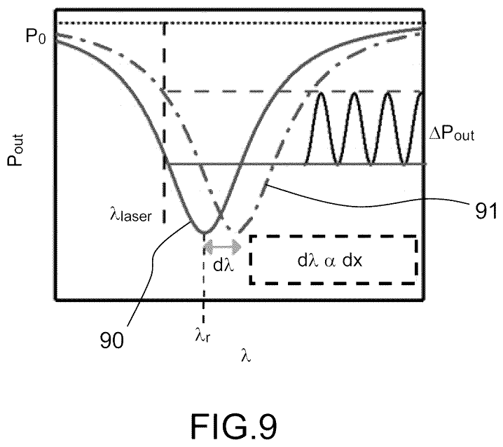

As a mechanical resonator, the resonator OMR may vibrate at the resonant frequency frm/o. The novelty of the elementary sensor according to the invention is that the ability of the optical resonator OMR to vibrate is used as a transduction mechanism to modulate the light beam passing through it, as illustrated in FIG. 9, which describes the luminous power Pout detected at the output of the waveguide as a function of wavelength. The curve 90 represents the resonance at λr. The wavelength λₗₐₛₑᵣ lies in the optical band of resonance BPro of the resonator, which is of width λr/Qopt, i.e. λₗₐₛₑᵣ is located on one side of the optical resonant peak. When the resonator OMR vibrates mechanically it makes a movement Δx and induces a periodic change in the length PL of the optical path traced by the light, this inducing a variation dλ, in the resonant wavelength (Equation (1)). The modulation of the resonant wavelength dλ induces a modulation ΔPout of the output light wave at the frequency of vibration of Δx, i.e. at the resonant frequency frm/o, as illustrated in FIG. 9.

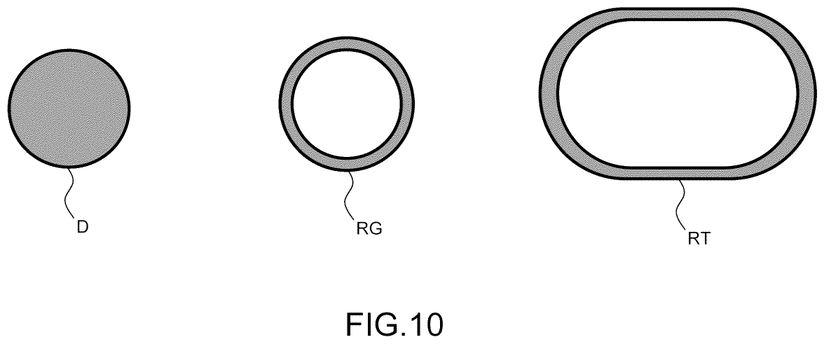

Preferably, the optomechanical resonator is selected from a disk D, a ring RG or a racetrack RT, as illustrated in FIG. 10.

Preferably, the resonators are excited via actuation selected from electrostatic actuation, piezoelectric actuation, and optical actuation.

The element ME is a mechanical element resonant at the frequency frm/e. The movement of the resonant mechanical element ME in proximity to the optomechanical resonator OMR (coupling of ME to OMR) causes a change in its effective refractive index neff (see Equation 1), and therefore a change in the resonant wavelength, and therefore modulates the output optical power at the frequency frm/e. It is this frequency frm/e that, through its perturbation, will allow the measurement of u or z (see description of the prior art).

Specifically, each ME has a resonant frequency sensitive to the measurand. Typically, via feedback, the excitation frequency fex/e(i,j) is matched to the frequency of each element, which varies during the measurement, in order to maintain the resonance of the mechanical element despite the perturbation. This is done, for example, using an oscillator and a frequency measurement, or indeed a phase-locked loop.

It is thus, in the system according to the invention, a question of a double modulation of the output power via modulation of the resonant wavelength:
on the one hand via the mechanical vibration of the optomechanical resonator OMR itself, which modifies the optical path length PL of the optomechanical resonator, and
on the other hand via the vibration of the resonant mechanical element ME, which modifies the effective refractive index neff of the optomechanical resonator to which it is coupled (movement in proximity to the resonator but not making contact).

The double modulation may be performed on the transmitted light wave, as illustrated in FIG. 10, or on its reflection.

The resonant mechanical element is preferably selected from a (cantilevered) beam, a disk, and a suspended platform.

Preferably, a resonant mechanical element is excited via actuation selected from electrostatic actuation, piezoelectric actuation, and thermal actuation.

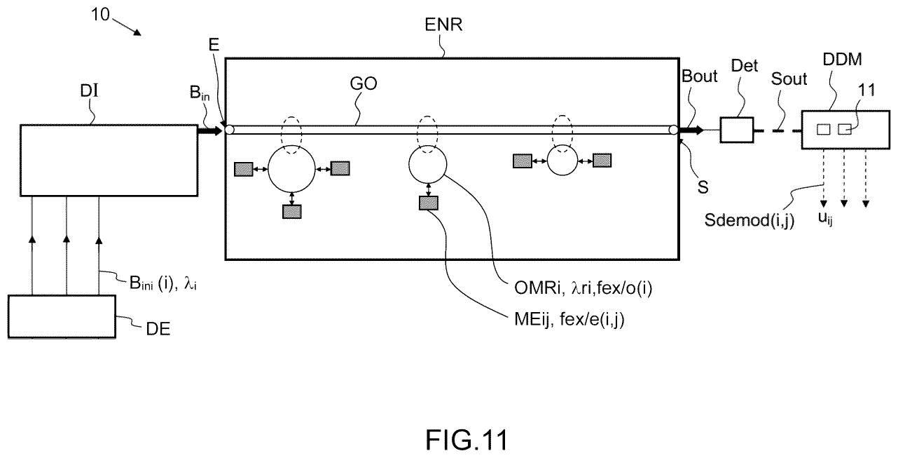

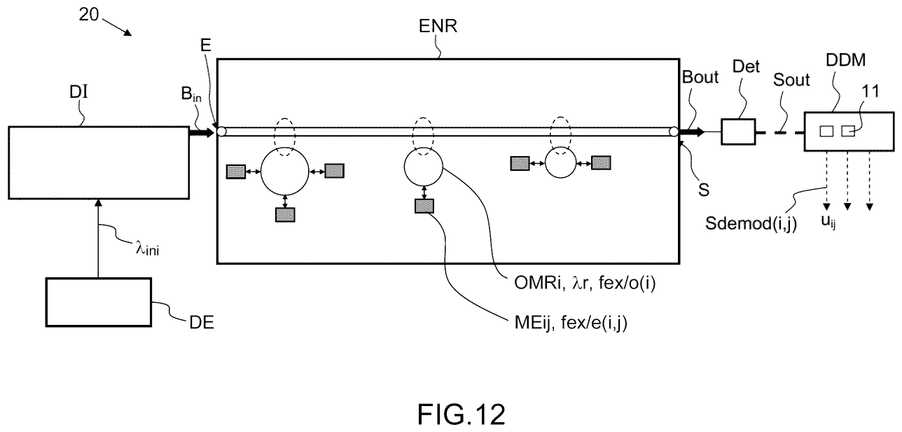

This double modulation associated with the pair (OMRi, MEij) is applied in a resonant assembly ENR according to the invention (illustrated in FIGS. 11 and 12) which resonant assembly comprises, as explained above, the plurality of optomechanical resonators OMRi, one resonator being associated with at least one resonant mechanical element MEij. An elementary sensor Cij made up of the pair (OMRi, ME(i,j)) allows uij/zij to be measured.

To implement the resonant assembly in the measuring system, the resonator must be excited in its band of mechanical resonance. Thus, each resonator OMRi of the resonant assembly is configured to be excited at an excitation frequency fex/o(i), called the first excitation frequency, and to modulate the light beam associated with the first excitation frequency fex/o(i). The first excitation frequency fex/o(i) lies in a first band of mechanical resonance BPrm/o(i) of the resonator. The best response is obtained for fex/o(i)=frm/o(i), but operation with an excitation in the vicinity of frm/o is also possible.

Likewise, a resonant mechanical element must be excited in its band of mechanical resonance. A resonant mechanical element MEij is configured to be excited at an excitation frequency fex/e(i,j), called the second excitation frequency. The value of the resonant frequency frm/e is perturbed by the measurand, and the second excitation frequency is modified accordingly to keep the element ME at resonance.

The best response is obtained when the excitation is at the resonant frequency of the resonant mechanical element, but operation with an excitation in the vicinity of the resonant frequency is also possible (second resonant bandwidth).

The resonant mechanical element is configured to modify an optical transmission or reflection in the vicinity of the optical resonance of the associated resonator, the modification being dependent on a physical quantity u to be measured.

It will be noted that a plurality of physical quantities may be measured, with mechanical elements sensitive to different physical quantities.

Subjected to these two excitations, the output beam is thus modulated at frequencies fex/o(i)+/−fex/e(i,j).

The following notations are used: Δi=2·π·fex/o(i) and Ωij=2·π·fex/e(i,j).

The angular frequency Δi is the result of modulation by the optomechanical resonator OMRi, and the angular frequency Ωij is the result of modulation by the resonant mechanical element MEij.

The measuring system also comprises an emission device DE for emitting the light wave, an injection device for injecting this light wave into the input of the resonant assembly, at least one detector Det configured to detect the light beam Bout obtained from the beam output from the resonant assembly and to generate an output signal Sout.

In accordance with the principle described in document EP4109049, the measuring system lastly comprises a demodulation device DDM comprising a plurality of so-called LIA demodulation modules 11 employing synchronous detection, for demodulating the output signal so as to extract characteristic signals Sdemod(i,j) associated with each resonant mechanical element. The measured values (uij, zij) of the physical quantity (associated with the resonant mechanical element) are determined from these characteristic signals. As explained above, it is possible to measure a plurality of physical quantities using mechanical elements sensitive to different physical quantities.

According to one example, the demodulation is carried out with at least N demodulation modules. According to another example, the number of demodulation modules is reduced through time-division multiplexing.

It may be seen that, compared with the measuring system of document EP4109049, the measuring system according to the invention no longer comprises an external modulator for modulating the light at the frequency fmod(i), since it is the optomechanical resonators OMRi themselves that perform this function. This simplifies the architecture of the system and makes it more integrable.

The measuring system according to the invention comes in two variants.

The measuring system 10 according to the first variant of the invention is illustrated in FIG. 11. In this first variant, the optomechanical resonators OMRi are configured to have optical resonant wavelengths λri that are all different. The emission device DE is then configured to emit a plurality of N light beams Bini(i) each having an associated emission wavelength λi lying in the associated band of resonance BPro(i) of the optical resonator (which band is centred on λri). According to one embodiment, the emission device comprises N lasers configured to emit the N light beams.

The measuring system 20 according to the second variant of the invention is illustrated in FIG. 12. In this second variant, the optomechanical resonators OMRi are configured to have a common optical resonant wavelength λr. The emission device DE is then configured to emit a light beam having the emission wavelength λini lying in the band of resonance of the associated optical resonator BPro (which is identical for all the optomechanical resonators and centred on λr), and forming the input beam Bin.

The mechanical resonant frequencies of the optomechanical resonators are selected so that their bands of mechanical resonance do not overlap.

It will be noted, as explained above, that in both variants each optomechanical resonator OMRi is configured to have a mechanical resonant frequency different from those of the other optomechanical resonators OMRk≠i.

The first variant has the advantage of simplicity of implementation, but comprises a plurality of lasers, and a laser is an expensive component that consumes a lot of power.

The second variant is more complex to implement, but has the advantage of requiring only one laser.

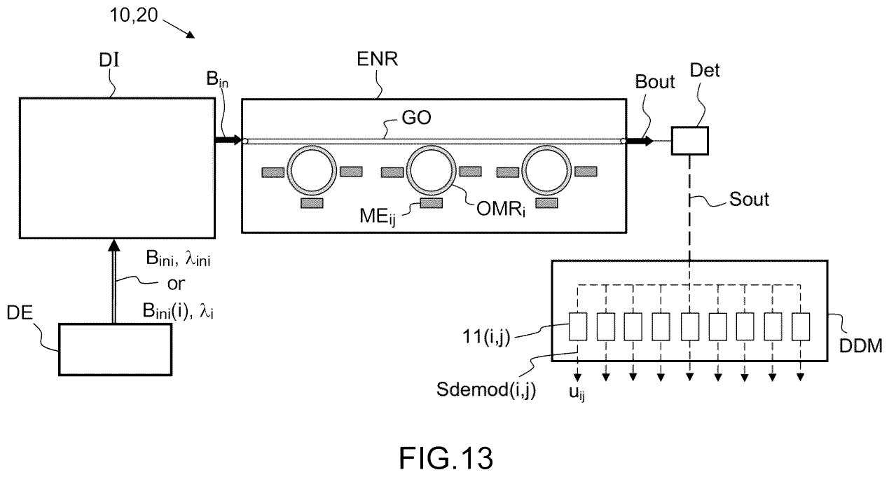

According to one embodiment compatible with both variants and illustrated in FIG. 13, the resonant assembly ENR comprises in all P resonant mechanical elements, and the demodulation device DDM comprises P LIA demodulation modules 11(i,j) configured to perform P demodulations at frequencies fex/o(i)+/−fex/e(i,j), respectively. This demodulation mode, which is said to be “one-stage”, is described in document EP4109049.

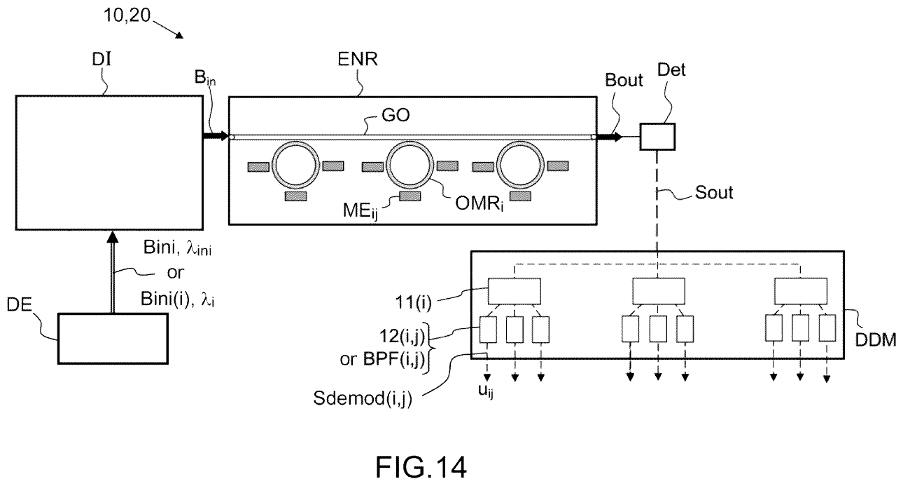

According to another embodiment compatible with both variants and illustrated in FIG. 14, the demodulation mode is said to be “two-stage” (also described in document EP4109049). The resonant assembly ENR comprises a first stage comprising N LIA demodulation modules 11(i) configured to perform N demodulations at frequencies fex/o(i), respectively.

According to a first option, the assembly ENR comprises, for each channel i, a second stage comprising demodulation modules 12(i,j) demodulating at frequencies fex/e(i,j). According to yet another embodiment, the assembly ENR comprises, for each channel i, a second stage comprising spectral filters BPF(i,j) configured to perform spectral filtering around the frequency fex/e(i,j).

According to one embodiment that is also described in document EP4109049, a LIA demodulation module comprises a reference oscillator at a demodulation frequency and a first demodulation pipeline comprising a mixer and a low-pass filter. Preferably, a LIA demodulation module also comprises a second demodulation pipeline in quadrature with the first pipeline.

In respect of the design and production of optomechanical resonators according to the first variant, in one embodiment the resonators OMRi are configured so that path lengths PLi of the light in the resonators are different from one resonator to another, a path length PLi being related to the associated optical resonant wavelength λri by the following formula, derived from Equation 1:

$${λ}_{ri} = \frac{PLi \cdot {n}_{effi}}{m ( i )} \qquad ( 2 )$$

with:
PLi the optical path length of the light in the resonator OMRi,
n_{effi} the effective refractive index of the material of the resonator OMRi,
m(i) an integer greater than or equal to 1 selected for each i.

According to an embodiment that facilitates fabrication of the resonant assembly ENR, the resonators are disks of radii Ri made of the same material, and which respect the relationship:

$${λ}_{ri} = \frac{2 π Ri \cdot {n}_{eff}}{m ( i )}$$

with n_{eff} the effective refractive index of the material of the discs.

Specifically, in the case of a disc or circular track of radius R, the length PL of one resonator turn (i.e. of the perimeter) is equal to 2·π·R.

According to one practical example of implementation for a set of two resonators consisting of silicon disks (effective index n=3.47), the radius of the first optical resonator is R₁=5 μm, and the radius of the second resonator is R₂=5.05 μm, and hence λ=1557 nm and λ₂=1573 nm, with m=70 in both cases.

In practice, the parameter Ri/m(i) is adapted to obtain a chosen resonant length.

In respect of the design and production of optomechanical resonators according to the second variant, in a first embodiment the resonators OMRi are configured so that the resonators OMRi are made of the same material and configured so that the path lengths PLi of the light in the resonators are different from one resonator to another, a path length being related to the optical resonant wavelength λr by the following formula:

$${λ}_{r} = \frac{PLi \cdot {n}_{eff}}{m ( i )}$$

with:
PLi the optical path length of the light in each of the resonators OMRi,
n_{eff} the effective refractive index of the material of said resonators OMRi,
m(i) an integer greater than or equal to 1 selected for each i.

According to one option, the resonators are discs of radii Ri made of the same material, and that respect the relationship:

$${λ}_{r} = \frac{2 π Ri \cdot {n}_{eff}}{m ( i )}$$

According to one practical example of implementation, for a set of two resonators consisting of silicon disks, and in the case where a single resonant wavelength λᵣ=1557.33 nm is used for both resonators, the following are obtained:

$$Resonator 1 : {R}_{1} = 5 μm , {m}_{1} = 70$$

$$Resonator 2 : {R}_{2} = 5.07 μm , {m}_{2} = 71$$

Thus, by changing the two parameters R and m, it is possible to set λᵣ. In this case, the sensors are differentiated by virtue of the first excitation frequency (optical modulation frequency), which is set by the radius R, and the measuring system then operates with a single laser.

According to a second embodiment, the resonators are made of the same material and have identical dimensions (for example discs of same radius), the various mechanical resonant frequencies being obtained by modification, from one resonator to another, of the positions of elements anchoring the resonators.

In this embodiment, only one laser is required, because all the optical resonators have the same resonant wavelength. Selectivity is achieved via the mechanical resonant frequency, which varies from one resonator to another. Consequently, the complexity of the reading system is lower.

According to one embodiment, at least a second excitation frequency of a resonant mechanical element coupled to one resonator is identical to a second excitation frequency of a resonant mechanical element coupled to another resonator. Specifically, what is important is for the mechanical resonant frequencies and therefore excitation frequencies of the mechanical elements coupled to a given optomechanical resonator to all be different, so that the demodulation may take place correctly.

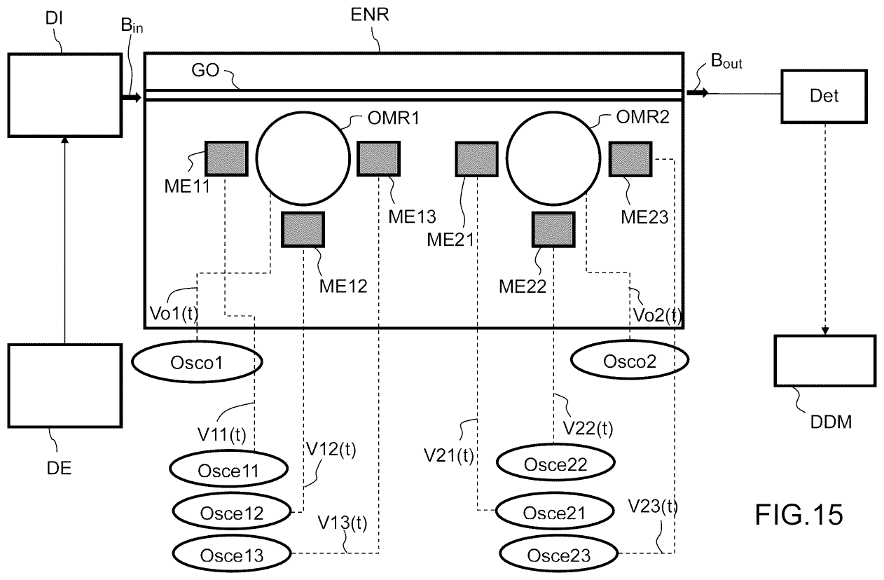

As regards implementation of the system (10 or 20) according to the invention, the first excitation frequencies fex/o(i) of the resonators OMRi are preferably generated via dedicated oscillators Oscoi, as illustrated in FIG. 15 for a set of two optomechanical resonators, each coupled to three resonant mechanical elements. Likewise, the second excitation frequencies fex/e(i,j) of the resonant mechanical elements MEij are preferably generated via dedicated oscillators Osceij. The signal generated by the oscillator Oscoi is denoted Voi(t), and the signal generated by the oscillator Osceij is denoted Vij(t).

The oscillators Oscoi form a first set of oscillators EO1 and the oscillators Osceij form a second set of oscillators EO2.

Each resonator OMRi or resonant mechanical element EMij resonates mechanically only with a frequency lying in its band of mechanical resonance, and it is therefore possible for all or some of the excitation signals to transit via a common bus. A resonator excited with a plurality of signals “recognises” its excitation signal and ignores the others.

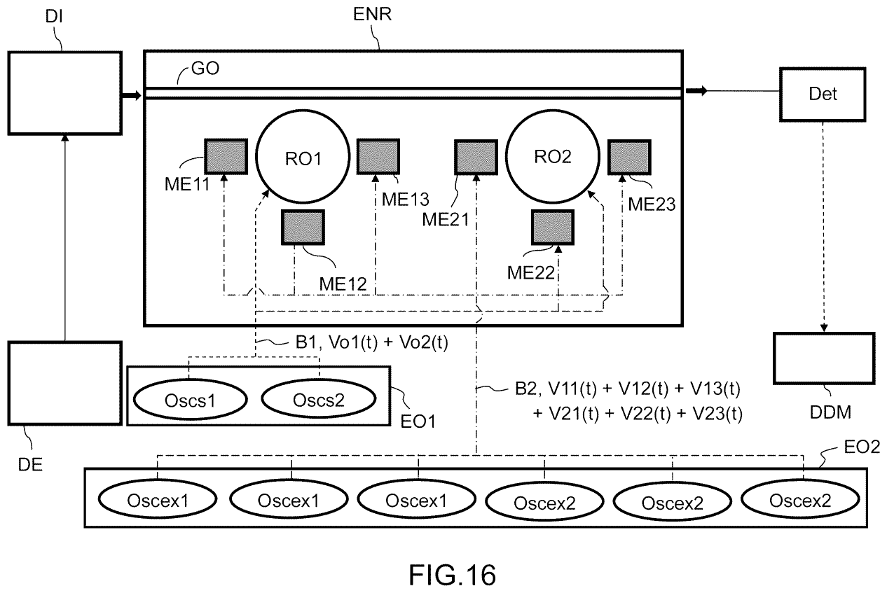

Thus according to one embodiment illustrated in FIG. 16, signals generated by the oscillators of the first set transit over a first common bus B1 for exciting the resonators and/or the signals generated by the oscillators of the second set transit over a second common bus B2 for exciting the resonant mechanical elements. Depending on constraints on implementation, the signals desired may be placed on a common bus.

Employment of common buses simplifies the fabrication and integration of the resonant assembly and its excitation.

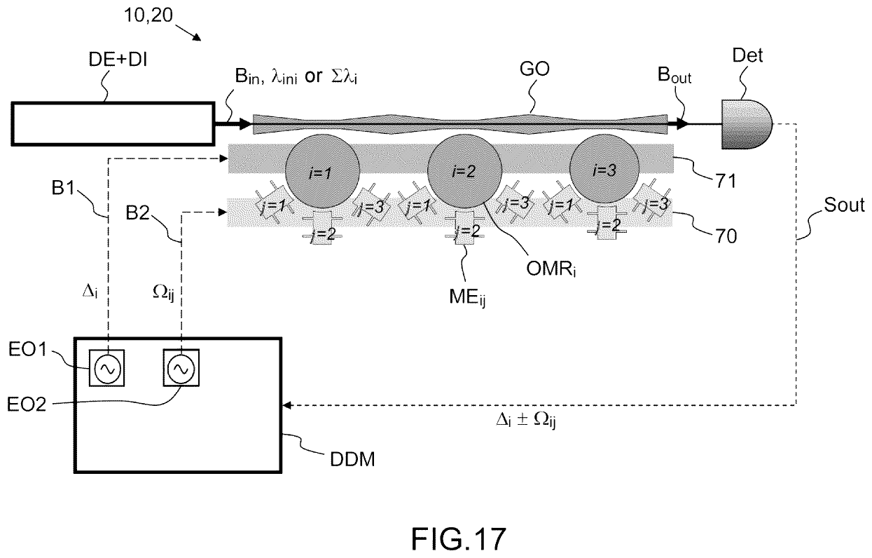

According to one embodiment, the resonators OMRi are actuated via first electrodes EL1 that are connected to one another and that are connected to the first bus B1, as illustrated in FIG. 17 (i=3, j=3). In FIG. 17, the electrodes EL1 and their connections have been represented by the region 71. Likewise, according to one embodiment, the resonant mechanical elements MEij are actuated via second electrodes EL2 that are connected to one another and that are connected to the second bus B2 (the electrodes EL2 and their connections have been represented by the region 70).

This electrode and bus structure simplifies implementation of the system according to the invention.

Preferably, the oscillators of the first and second sets are used to generate demodulation frequencies.

Preferably, the oscillators are integrated into the demodulation device DDM, as illustrated in FIG. 17.

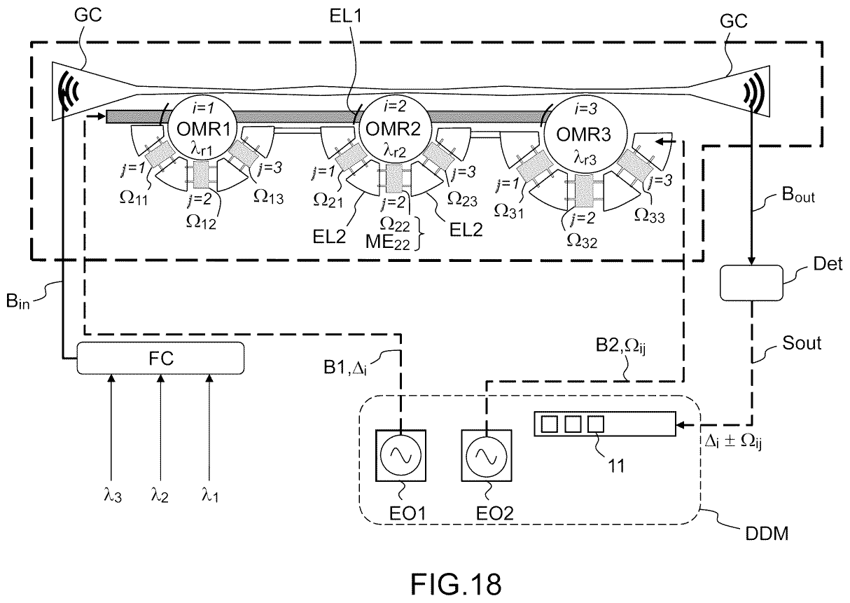

According to one embodiment, the resonant assembly ENR is integrated into a chip CHIP as illustrated in FIG. 18 in one example according to the first variant. In this example, the injection device DI comprises a fibre coupler FC that superposes the N light beams to form the beam Bin and a grating coupler GC that injects Bin into the waveguide GO, and that is also integrated into the chip CHIP.

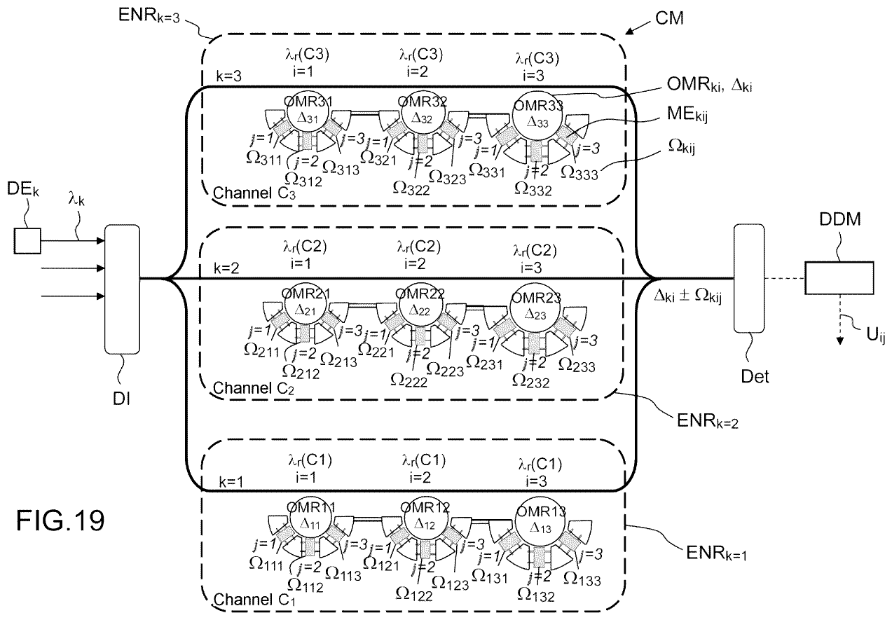

The invention also relates to a measuring sensor CM (illustrated in FIG. 19) comprising M systems according to the second variant. The system is indexed k and is called a channel. FIG. 19 illustrates the case where M=3, each resonant assembly comprising N=3 optomechanical resonators each coupled to 3 resonant mechanical elements. The resonant assemblies ENRk operate in parallel: the inputs Ek and the outputs Sk of the M systems are merged so that the various channels operate in parallel. The injection device DI, the detector Det and the demodulation device DDM are common to all the channels.

The angular frequency of the mechanical excitation of resonator n°i of system k is denoted Δki and the angular frequency of the mechanical excitation of resonant element n°j coupled to resonator n°i of system k is denoted Ωkij.

Each channel k has an associated resonant wavelength λr(Ck).

Each emission device DEk is configured to emit a light beam having an emission wavelength λk lying in a band of resonance of the associated channel and the injection device DI is configured to superpose the M light beams to form the input beam Bin.

Wavelength multiplexing is thus achieved, allowing the number of elementary sensors Ckij (OMRki, MEkij) to be multiplied without adding complexity to the system, and while keeping a single input and a single output.

1. A MEMS or NEMS measuring system comprising:
a resonant assembly (ENR) comprising:
one input (E) and one output (S),
a plurality of N resonators OMRi indexed i, each resonator being configured to exhibit both an optical resonance at an optical resonant wavelength (λri) and a mechanical resonance at an associated mechanical resonant frequency (frm/o(i)), said optical resonant wavelengths and said mechanical resonant frequencies all being different,
at least one resonant mechanical element MEij coupled to each resonator OMRi, j being the index of the resonant mechanical element associated with the resonator OMRi, said resonant mechanical element having a mechanical resonant frequency (frm/e(i,j)), said mechanical resonant frequency being, where appropriate, different from the mechanical resonant frequencies of the other resonant mechanical elements coupled to a given resonator,
at least one waveguide (GO) to which the optical resonators are coupled,
an emission device (DE) configured to emit a plurality of N light beams each having an emission wavelength λi lying in an optical band of resonance (BPro(i)) of the associated optical resonator,
an injection device (DI) configured to superpose the N light beams to form an input beam (Bin) and to inject the input beam into the input of the resonant assembly,
each resonator OMRi of the resonant assembly further being configured to be excited at a mechanical excitation frequency (fex/o(i)) called the first excitation frequency, lying in a first band of mechanical resonance (BPrm/o(i)) of said resonator, and to modulate the light beam associated with said first excitation frequency (fex/o(i)),
a resonant mechanical element (MEij) being configured to be excited at a mechanical excitation frequency (fex/e(i,j)) called the second excitation frequency, and to modify an optical transmission or reflection in the vicinity of the optical resonance of said associated resonator, said modification being dependent on a physical quantity (u) to be measured,
at least one detector (Det) configured to detect a light beam obtained from the beam (Bout) output from the resonant assembly and to generate an output signal (Sout),
a so-called LIA demodulation device (DDM) comprising a plurality of demodulation modules employing synchronous detection, for demodulating the output signal, so as to extract characteristic signals (Sdemod(i,j)) associated with each resonant mechanical element, measured values (uij, zij) of said physical quantity being determined from said characteristic signals.

2. The Measuring system according to claim 1, wherein the resonators are configured so that path lengths (PLi) of the light in said resonators are different from one resonator to another, a path length being related to the associated optical resonant wavelength by the following formula:
$${λ}_{ri} = \frac{PLi \cdot {n}_{effi}}{m ( i )}$$
with PLi the optical path length of the light in the resonator OMRi,
n_{effi} the effective refractive index of the material of the resonator OMRi,
m(i) an integer greater than or equal to 1 selected for each i.

3. The measuring system according to claim 2, wherein the resonators are discs of radii Ri made of the same material, and that respect the relationship:
$${λ}_{ri} = \frac{2 π Ri \cdot {n}_{eff}}{m ( i )}$$
with n_{eff} the effective refractive index of the material of the discs.

4. The MEMS or NEMS measuring system comprising:
a resonant assembly (ENR) comprising:
one input (E) and one output (S),
a plurality of N resonators OMRi indexed i, each resonator being configured to exhibit both an optical resonance at an optical resonant wavelength (λr) common to all the resonators and a mechanical resonance at a mechanical resonant frequency (frm/o(i)) specific to each resonator, said mechanical resonant frequencies all being different,
at least one resonant mechanical element MEij coupled to each resonator OMRi, j being the index of the resonant mechanical element associated with the resonator OMRi, said resonant mechanical element having a mechanical resonant frequency (frm/e(i,j)), said mechanical resonant frequency being, where appropriate, different from the mechanical resonant frequencies of the other resonant mechanical elements coupled to a given resonator,
at least one waveguide (GO) to which the optical resonators are coupled,
an emission device (DE) configured to emit a light beam called the input beam (Bin) having an optical wavelength λini lying in an optical band of resonance (BPro) that is identical for all the optical resonators,
an injection device (DI) configured to inject said input beam (Bin) into the input of the resonant assembly,
each resonator OMRi of the resonant assembly further being configured to be excited at a mechanical excitation frequency (fex/o(i,j)), called the first excitation frequency, lying in a first band of mechanical resonance (BPrm/o(i)) of said resonator, and to modulate the light beam associated with said first excitation frequency (fex/o(i,j)),
a resonant mechanical element being configured to be excited at a mechanical excitation frequency (fex/e(i,j)) called the second excitation frequency, and to modify an optical transmission or reflection in the vicinity of the optical resonance of said resonator, said modification being dependent on a physical quantity (u) to be measured,
at least one detector (Det) configured to detect a light beam obtained from the beam (Bout) output from the resonant assembly and to generate an output signal (Sout),
a so-called LIA demodulation device (DDM) comprising a plurality of demodulation modules employing synchronous detection, for demodulating the output signal, so as to extract characteristic signals (Sdemod(i,j)) associated with each resonant mechanical element, measured values (uij, zij) of said physical quantity being determined from said characteristic signals.

5. The measuring system according to claim 4, wherein the resonators are made of the same material and configured so that the path lengths (PLi) of the light in said resonators are different from one resonator to another, a path length being related to the optical resonant wavelength by the following formula:
$${λ}_{r} = \frac{PLi \cdot {n}_{eff}}{m ( i )}$$
with PLi the optical path length of the light in each of the resonators OMRi,
n_{eff} the effective refractive index of the material of said resonators OMRi,
m(i) an integer greater than or equal to 1 selected for each i.

6. The measuring system according to claim 5, wherein the resonators are discs of radii Ri made of the same material, and that respect the relationship:
$${λ}_{r} = \frac{2 π Ri \cdot {n}_{eff}}{m ( i )}$$

7. The measuring system according to claim 4, wherein the resonators are made of the same material and have identical dimensions, the various mechanical resonant frequencies being obtained by modification, from one resonator to another, of the positions of elements anchoring said disks.

8. The system according to claim 1, wherein a resonator is selected from: a disc, a ring, and a racetrack.

9. The system according to claim 1, wherein a resonator is excited via actuation selected from electrostatic actuation, piezoelectric actuation, and optical actuation.

10. The system according to claim 1, wherein a resonant mechanical element is selected from a beam, a disc, and a suspended platform.

11. The system according to claim 1, wherein a resonant mechanical element is excited via actuation selected from electrostatic actuation, piezoelectric actuation, and thermal actuation.

12. The system according to claim 1, wherein at least a second excitation frequency of a resonant mechanical element coupled to one resonator is identical to a second excitation frequency of a resonant mechanical element coupled to another resonator.

13. The system according to claim 1, wherein the resonators (OMRi) are excited at said associated first excitation frequencies (fex/o(i)) via dedicated oscillators (Oscoi), said oscillators forming a first set of oscillators (EO1), and wherein said resonant mechanical elements (MEij) are excited at said second excitation frequencies (fex/e(i,j)) via dedicated oscillators (Osceij), said oscillators forming a second set of oscillators (EO2).

14. The system according to claim 13, wherein signals generated by the oscillators of the first set transit over a first common bus (B1) for exciting the resonators and/or signals generated by the oscillators of the second set transit over a second common bus (B2) for exciting the resonant mechanical elements.

15. The system according to claim 14, wherein the resonators are actuated via first electrodes (EL1) that are connected to one other and that are connected to the first bus (B1).

16. The system according to claim 14, wherein the resonant mechanical elements are actuated via second electrodes (EL1) that are connected to one another and that are connected to the second bus (B2).

17. The measuring system according to claim 13, wherein said oscillators of the first and second sets are used to generate demodulation frequencies.

18. A measuring sensor comprising a plurality of M measuring systems according to claim 4, a measuring system being indexed k and forming a channel k, each channel having an associated resonant wavelength (λrC(k)),
said inputs (Ek) and said outputs (Sk) merging so that the various channels operate in parallel,
the injection device (DI), the detector (Det) and the demodulation device (DDM) being common to all the channels,
each emission device (DEk) being configured to emit a light beam having an emission wavelength λk lying in a band of resonance of the associated channel and the injection device (DI) being configured to superpose the M light beams to form said input beam (Bin).
